(19) United States
(12) Patent Application Publication
(10) Pub. No.: US 2025/0212422 A1
(43) Pub. Date: Jun. 26, 2025

(54) SYSTEMS AND METHODS FOR HIGH DENSITY SYSTEM ON CHIP MEMORY INTEGRATION

(71) Applicant: Meta Platforms Technologies, LLC, Menlo Park, CA (US)

(72) Inventors: Rajendra D. Pendse, Fremont, CA (US); Alok Kumar Mathur, Cupertino, CA (US); Jaspreet Singh Gandhi, San Jose, CA (US); Aswani Kurra, Surrey, CA (US); Janani Chandrasekhar, Fremont, CA (US)

(21) Appl. No.: 18/390,987

(22) Filed: Dec. 20, 2023

(51) Int. Cl. H10B 80/00; H01L 21/48; H01L 23/00; H01L 23/538; H01L 25/00; H01L 25/10

(52) U.S. Cl. CPC H10B 80/00; H01L 21/4853; H01L 21/4857; H01L 23/5383; H01L 23/5386; H01L 23/5389; H01L 24/20; H01L 25/105; H01L 25/50; H01L 2224/214; H01L 2225/1035; H01L 2225/1052; H01L 2924/1436; H01L 2924/1437

(57) ABSTRACT

A method may include mounting a system on chip face down on a fanout package structure in a manner that bonds the system on chip face to face with one or more functional chips included in the fanout package structure. The method may also include mounting an additional functional chip on the system on chip and bonding the additional functional chip to the system on chip. Various other methods, systems, and computer-readable media are also disclosed.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for high density system on chip memory integration.

FIG. 2 is an illustration of exemplary systems for high density system on chip memory integration.

FIG. 3 is an illustration of an exemplary semiconductor device package for high density system on chip memory integration.

FIG. 4 is an illustration of an exemplary semiconductor device package for high density system on chip memory integration.

FIG. 5 is an illustration of exemplary augmented-reality glasses that may be used in connection with embodiments of this disclosure.

FIG. 6 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Current technologies for system on chip (SoC) dynamic random access memory (SoC-DRAM) packaging in a mobile segment include traditional package on package (POP), integrated fanout (InFO) package on package (InFO_POP), molded chip embedded package (MCep), and integrated package on package (iPoP). However, these technologies are limited to two part 3D stacking.

The present disclosure is generally directed to systems and methods for high density system on chip memory integration. As will be explained in greater detail below, embodiments of the present disclosure may mount a system on chip face down on a fanout package structure in a manner that bonds the system on chip face to face with one or more functional chips included in the fanout package structure, mount an additional functional chip on the system on chip, and bond the additional functional chip to the system on chip. In one example, the disclosed systems and methods may mount the additional functional chip back to back on the system on chip by an adhesive and bond the additional functional chip to the system on chip by wire bonding. In another example, the disclosed systems and methods may mount the additional functional chip face to back on the system on chip and bond a face of the additional functional chip to through silicon vias in the system on chip.

Benefits arising from the disclosed systems and methods may include achievement of three-part 3D stacking at reduced cost, reduced cycle time, and/or reduced package height. In some implementations, these benefits may enable a three-part system exhibiting a low-latency and high bandwidth in-package memory (e.g., that performs analogously to an on-chip SRAM), a highly functional SoC, and a high-capacity storage (e.g., DRAM) with reduced cost and cycle time and a reduced package height. This reduced package height may be beneficial in meeting form factor requirements for use of the disclosed systems and methods in space-constrained mobile devices, such as virtual reality (VR) headsets and augmented reality (AR) glasses. The reduced cost and cycle time may be beneficial in achieving space-constrained mobile devices, such as VR headsets and AR glasses, at reduced time and cost.

Features from any of the embodiments described herein may be used in combination with one another in accordance with the general principles described herein. These and other embodiments, features, and advantages will be more fully understood upon reading the following detailed description in conjunction with the accompanying drawings and claims.

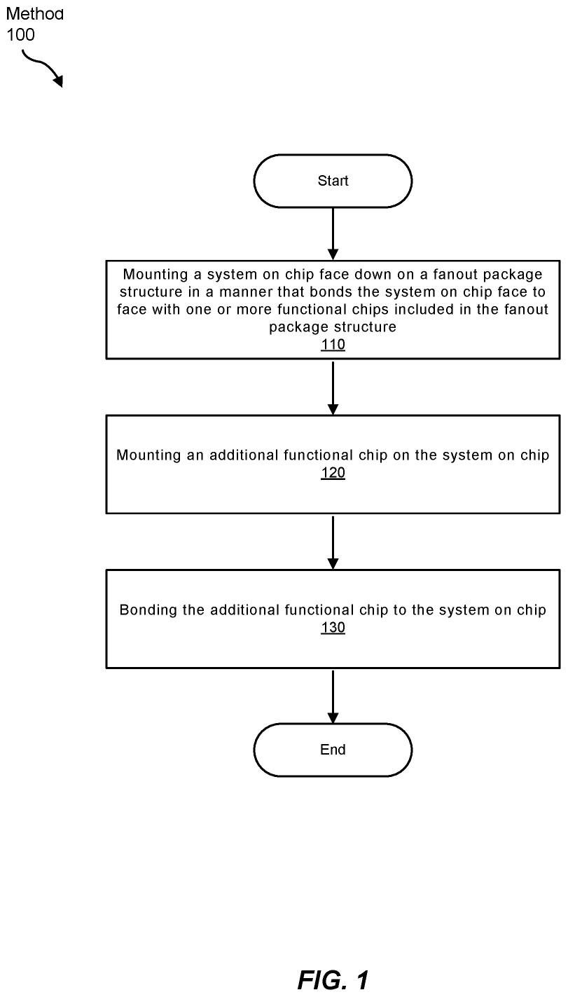

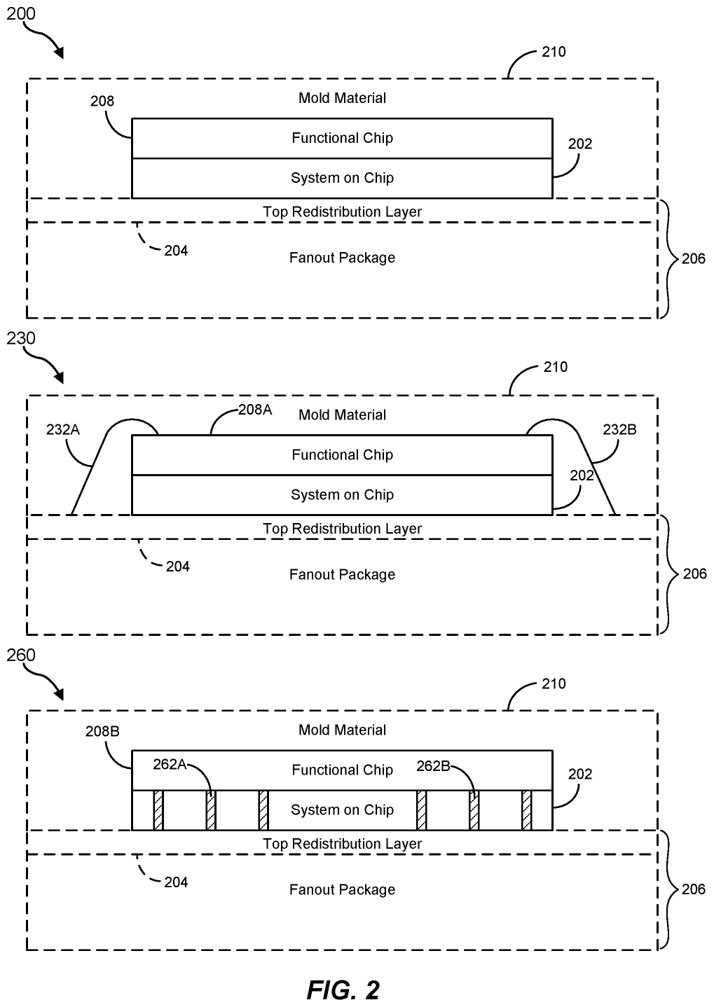

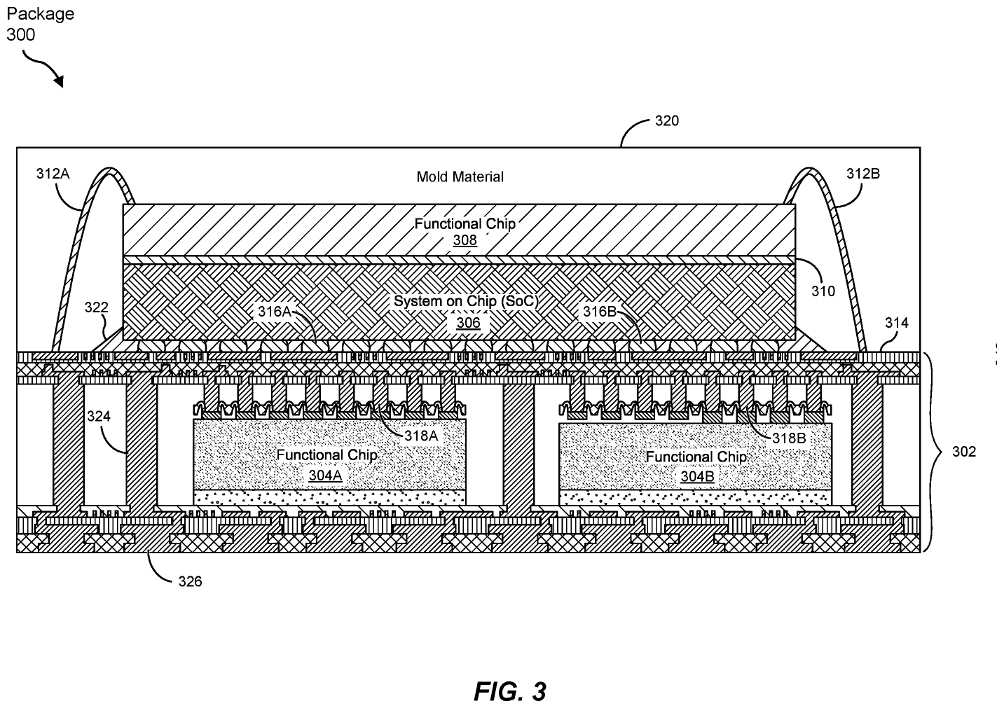

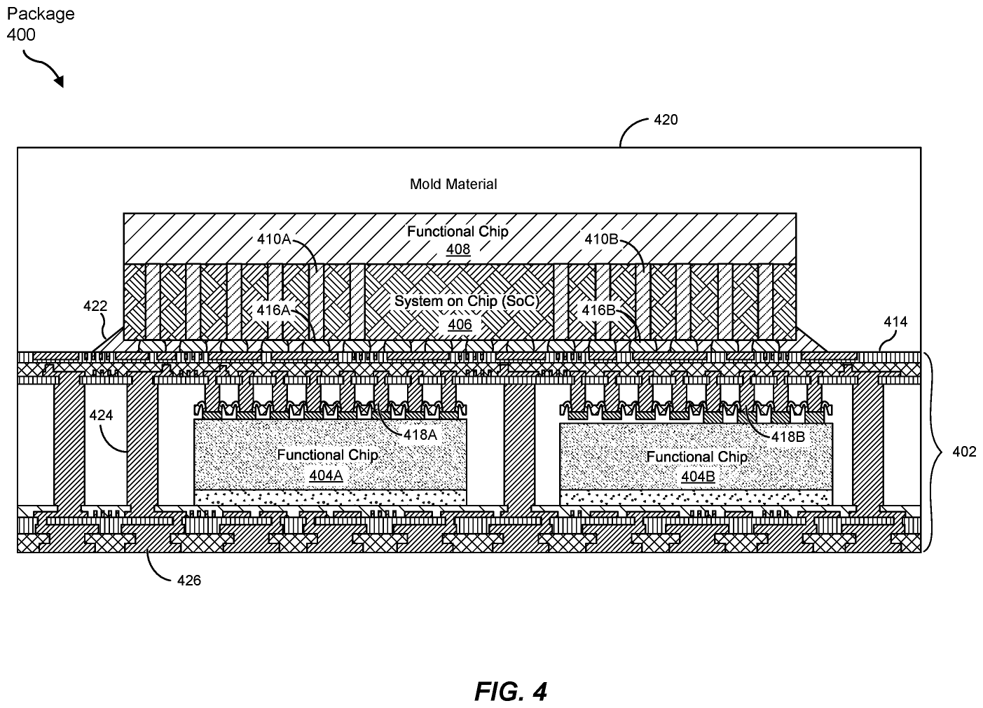

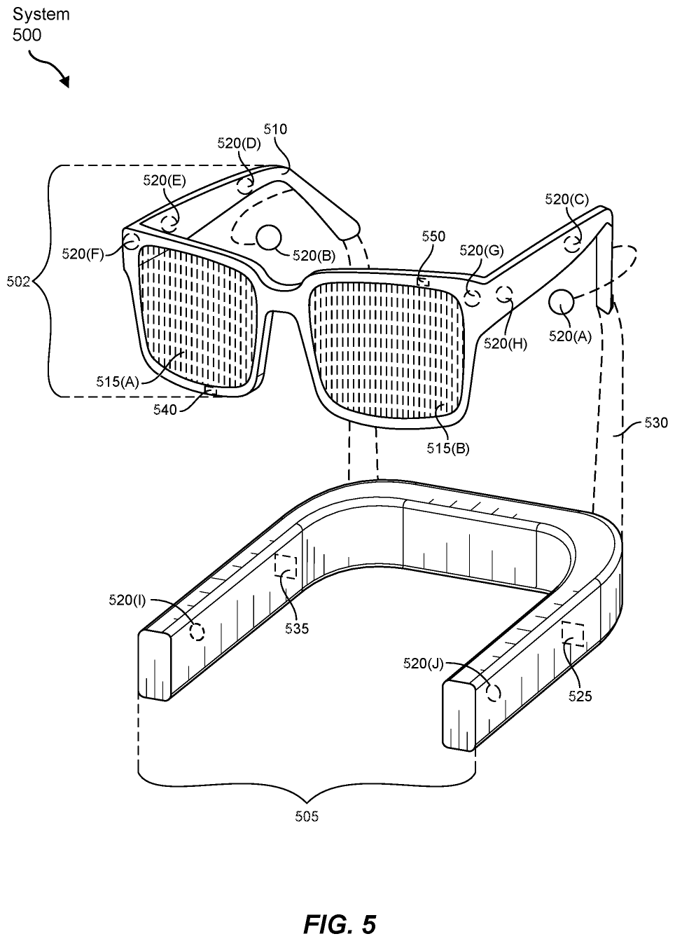

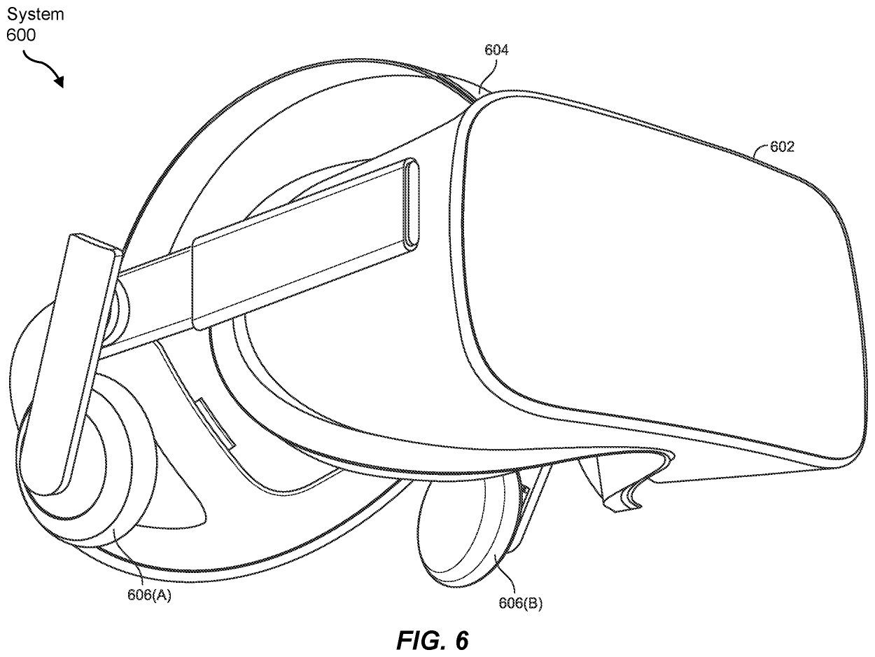

The following will provide, with reference to FIG. 1, detailed descriptions of exemplary methods for high density system on chip memory integration. Additionally, exemplary systems for high density system on chip memory integration will be provided in connection with FIG. 2. Exemplary semiconductor device packages for high density system on chip memory integration will be provided in connection with FIGS. 3 and 4. Further, detailed descriptions of exemplary augmented-reality glasses and virtual-reality headsets will be provided with reference to FIGS. 5 and 6.

FIG. 1 is a flow diagram of an exemplary method 100 for high density system on chip memory integration. Beginning at step 110, method 100 may include mounting a system on chip. For example, method 100, at step 110, may mount a system on chip face down on a fanout package structure in a manner that bonds the system on chip face to face with one or more functional chips included in the fanout package structure.

The term “system on chip,” as used herein, may generally refer to an integrated circuit that integrates most or all components of a computer or other electronic system. For example, and without limitation, these components may include an on-chip central processing unit (CPU), memory interfaces, input/output devices and interfaces, and secondary storage interfaces, often alongside other components such as radio modems and a graphics processing unit (GPU)—all on a single substrate or microchip. With an SoC, a chip might incorporate a CPU, plus an additional one-hundred IP blocks on the same chip. That design may then be scaled by moving to the next node, which is an expensive process. With a chiplet model, those one-hundred IP blocks may be hardened into smaller dies or chiplets.

The term “fanout package structure,” as used herein, may generally refer to any package or structure therein with connections fanned-out of a chip surface, enabling more external I/Os. For example, and without limitation, conventional fan-out packages may use an epoxy mold compound to fully embed the dies, rather than placing them upon a substrate or interposer. Fan-Out packaging may typically involve dicing chips on a silicon wafer, and then very precisely positioning the known-good chips on a thin “reconstituted” or carrier wafer/panel. These chips may then be molded and followed by a redistribution layer (RDL) atop the molded area (e.g., chip and fan-out area), and then solder balls may be formed on top. A popular packaging technique (e.g., embedded die packaging) may involve building packages with a standard Fan-Out type RDL, but with dies embedded in materials such as organic laminate or silicon wafer instead of the mold compound.

The term “functional chip,” as used herein, may generally refer to a set of electronic circuits on a small flat piece of silicon. For example, and without limitation, a functional chip may correspond to a static random access memory (SRAM) or a dynamic random access memory (DRAM). In this context, the term “memory” may refer to an electronic holding place for instructions and data a computer needs to reach quickly. Also in this context, the term “static random access memory” may refer to a type of random access memory (RAM) that retains data bits in its memory as long as power is being supplied. In contrast, the term “dynamic random access memory” may refer to a type of RAM which must be continuously refreshed.

Method 100 may perform step 110 in various ways. For example, method 100 may, at step 110, mount the system on chip on a redistribution layer of the fanout package structure by at least one of copper pillars or solder balls. In some implementations, the one or more functional chips of the fanout package structure may correspond to an in-package high speed local memory that performs analogously to an on-chip static random access memory.

The “redistribution layer,” as used herein, may generally refer to a wiring layer (e.g., formed of copper) and an insulating layer. For example, and without limitation, a redistribution layer (RDL) may be used in fan out and other types of packaging structures. Its function may be to connect a semiconductor chip to a board connector.

The term “copper pillar,” as used herein, may generally refer to terminals used to “flip-chip” IC chips to a substrate in a semiconductor package. For example, and without limitation, copper pillars may utilize Thermal Compression Flip-Chip (TCFC) technology. Copper pillars may be formed on aluminum electrode pads of an IC chip.

The term “solder ball,” as used herein, may generally refer to small balls of solder that form on a printed circuit board (PCB) during soldering. For example, and without limitation, solder balls may be formed of a low-melting alloy, such as one based on lead and tin or (e.g., for higher temperatures) on brass or silver, that may be used for joining less fusible metals.

At step 120, method 100 may include mounting an additional functional chip. For example, method 100, at step 120, may mount an additional functional chip on the system on chip.

Method 100 may perform step 120 in various ways. For example, method 100 may, at step 120, mount the additional functional chip back to back on the system on chip (e.g., by an adhesive). In another example, method 100 may, at step 120, mount the additional functional chip face to back on the system on chip. In some implementations, the additional functional chip may correspond to a dynamic random access memory.

At step 130, method 100 may include bonding the additional functional chip. For example, method 100, at step 130, may bond the additional functional chip to the system on chip.

Method 100 may perform step 130 in various ways. For example, in implementations in which method 100 mounts, at step 120, the additional functional chip back to back on the system on chip, method 100 may, at step 130, bond the additional functional chip to the system on chip by wire bonding. In other implementations in which method 100 mounts, at step 120, the additional functional chip face to back on the system on chip, method 100 may, at step 130, bond a face of the additional functional chip to through silicon vias in the system on chip (e.g., by copper pillars, copper pads, and/or solder balls). In some implementations, method 100 may, at step 130, surround the system on chip and the additional functional chip with a mold material.

The term “wire bonding,” as used herein, may generally refer to a method of making interconnections between an integrated circuit (IC) or other semiconductor device and its packaging during semiconductor device fabrication. For example, and without limitation, wire bonding may be used to connect an IC to other electronics or to connect from one printed circuit board (PCB) to another. Wire bonding may generally be considered the most cost-effective and flexible interconnect technology and may be used to assemble the vast majority of semiconductor packages.

The term “through silicon vias,” as used herein, may generally refer to vertical wires used to precisely connect stacked chips. For example, and without limitation, through silicon vias (TSVs) may be formed by etching trenches into silicon and then filling them with insulating liners and metal wires. vertical electrical connection (via) that passes completely through a silicon wafer or die. TSVs may be categorized as high-performance interconnect techniques used as an alternative to wire-bond and flip chips to create 3D packages and 3D integrated circuits. Compared to alternatives such as package-on-package, the interconnect and device density may be substantially higher and the length of the connections may be shorter.

The term “mold material,” as used herein, may generally refer to a mold compound. For example, and without limitation, mold compounds may be composite materials that include organic resins, such as epoxy resin, which may be melted. Given the natural adhesive properties of epoxy resins, these compounds may also include a mold release agent to enable the extraction of the component from a mold. Phenolic hardeners, silicas, pigments, and catalysts may also be featured in mold compounds to accelerate cure reactions. In this context, mold compounds may be used to encapsulate a range of electronic packages, including capacitors, transistors, central processing units, and memory devices. In basic terms, the process may be considered in two stages. First, the components to be encapsulated may be transferred into mold cavities. Following this stage, a mold compound, having been liquefied by either heat or pressure, may be forced into the cavity where it may solidify into a plastic encapsulated device. Molding processes may also include an underfill, which may correspond to an adhesive. For example, and without limitation, the underfill may be dispensed on a flip-chip placement site. The chip may then be placed on top of the underfill under force to press the die into the fluid and the bumps into contact with the pads.

FIG. 2 illustrates systems 200, 230, and 260 for high density system on chip memory integration that may correspond to implementations of method 100 of FIG. 1. For example, system 200 may include a system on chip 202 mounted face down on a top redistribution layer 204 of a fanout package 206 and a functional chip 208 mounted on the system on chip 202. In some implementations, the system on chip 202 and the functional chip 208 may be surrounded by a mold material 210. In some implementations, the functional chip 208 may correspond to a dynamic random access memory.

System 230 may correspond to an implementation of system 200. For example, system 230 may include the system on chip 202 mounted face down on the top redistribution layer 204 of the fanout package 206. System 230 may also include a functional chip 208A that may correspond to the functional chip 202 of system 200 in an implementation in which the functional chip 208A is mounted face up (e.g., back to back) atop the system on chip 202 (e.g., by an adhesive). In this implementation, functional chip 208A may be bonded to the system on chip 202 using wire bonds 232A and 232B that connect a face of the functional chip 208A to the top redistribution layer 204 of the fanout package 206. In some implementations, the system on chip 202, the functional chip 208A, and the wire bonds 232A and 232B may be surrounded by the mold material 210. As in system 200, the functional chip 208A may correspond to a dynamic random access memory in some implementations.

System 260 may correspond to an implementation of system 200. For example, system 260 may include the system on chip 202 mounted face down on the top redistribution layer 204 of the fanout package 206. System 260 may also include a functional chip 208B that may correspond to the functional chip 202 of system 200 in an implementation in which the functional chip 208B is mounted face down (e.g., face to back) atop the system on chip 202. In this implementation, functional chip 208B may be bonded to the system on chip 202 by through silicon vias 262A and 262B in the system on chip. These through silicon vias 262A and 262B may connect a face of the functional chip 208B to the top redistribution layer 204 of the fanout package 206. In some implementations, the system on chip 202 and the functional chip 208B may be surrounded by the mold material 210. As in some implementations of system 200, the functional chip 208B may correspond to a dynamic random access memory.

FIG. 3 illustrates a semiconductor device package 300 for high density system on chip memory integration that may correspond to implementations of method 100 of FIG. 1 and/or system 230 of FIG. 2. For example, the semiconductor device package 300 may include a fanout package structure 302 including one or more functional chips 304A and 304B. Additionally, the semiconductor device package 300 may include a system on chip 306 mounted face down on the fanout package structure 302 and bonded face to face with the one or more functional chips 304A and 304B. Also, the semiconductor device package 300 may include an additional functional chip 308 mounted on and bonded to the system on chip 306. In some implementations, the additional functional chip 308 may be mounted back to back on the system on chip 306 by an adhesive 310 and bonded to the system on chip by wire bonds 312A and 312B.

As shown in FIG. 3, the system on chip 306 may be mounted on a (e.g., top) redistribution layer 314 of the fanout package structure 302 by one or more connection elements 316A and 316B (e.g., copper pillars and/or solder balls). Similarly, additional connections 318A and 318B (e.g., copper pillars) may mount faces of the one or more functional chips 304A and 304B to the (e.g., top) redistribution layer 314. In this way, system on chip 306 may be mounted face to face with one or more functional chips 304A and 304B in the fanout package structure 302. In some implementations, the one or more functional chips 304A and 304B may correspond to an in-package high speed local memory that performs analogously to an on-chip static random access memory. Additionally or alternatively, the additional functional chip 308 may correspond to a dynamic random access memory.

As shown in FIG. 3, the semiconductor device package 300 may further include a mold material 320 surrounding the system on chip 306 and the additional functional chip 308. Wire bonds 312A and 312B may also be surrounded by the mold material 320. In some implementations, an under fill 322 may be provided around connection elements 316A and 316B as shown in FIG. 3. In some implementations, one or more through mold vias (TMVs) 324 may connect the (e.g., top) redistribution layer 314 to another (e.g., bottom) redistribution layer 326 of the fanout package structure 302.

FIG. 4 illustrates a semiconductor device package 400 for high density system on chip memory integration that may correspond to implementations of method 100 of FIG. 1 and/or system 260 of FIG. 2. For example, the semiconductor device package 400 may include a fanout package structure 402 including one or more functional chips 404A and 404B. Additionally, the semiconductor device package 400 may include a system on chip 406 mounted face down on the fanout package structure 402 and bonded face to face with the one or more functional chips 404A and 404B. Also, the semiconductor device package 400 may include an additional functional chip 408 mounted on and bonded to the system on chip 406. The additional functional chip 408 may be mounted face to back on the system on chip 406 and a face of the additional functional chip 408 may be bonded to through silicon vias 410A and 410B in the system on chip.

As shown in FIG. 4, the system on chip 406 may be mounted on a (e.g., top) redistribution layer 414 of the fanout package structure 402 by one or more connection elements 416A and 416B (e.g., copper pillars and/or solder balls). Similarly, additional connections 418A and 418B (e.g., copper pillars) may mount faces of the one or more functional chips 404A and 404B to the (e.g., top) redistribution layer 414. In this way, system on chip 406 may be mounted face to face with one or more functional chips 404A and 404B in the fanout package structure 402. In some implementations, the one or more functional chips 404A and 404B may correspond to an in-package high speed local memory that performs analogously to an on-chip static random access memory. Additionally or alternatively, the additional functional chip 408 may correspond to a dynamic random access memory.

As shown in FIG. 4, the semiconductor device package 400 may further include a mold material 420 surrounding the system on chip 406 and the additional functional chip 408. In some implementations, an under fill 422 may be provided around connection elements 416A and 416B as shown in FIG. 4. In some implementations, one or more through mold vias (TMVs) 424 may connect the (e.g., top) redistribution layer 414 to another (e.g., bottom) redistribution layer 426 of the fanout package structure 402.

As set forth above, the disclosed systems and methods for high density system on chip memory integration may mount a system on chip face down on a fanout package structure in a manner that bonds the system on chip face to face with one or more functional chips included in the fanout package structure, mount an additional functional chip on the system on chip, and bond the additional functional chip to the system on chip. In one example, the disclosed systems and methods may mount the additional functional chip back to back on the system on chip by an adhesive and bond the additional functional chip to the system on chip by wire bonding. In another example, the disclosed systems and methods may mount the additional functional chip face to back on the system on chip and bond a face of the additional functional chip to through silicon vias in the system on chip.

Benefits arising from the disclosed systems and methods may include achievement of three-part 3D stacking at reduced cost, reduced cycle time, and/or reduced package height. In some implementations, these benefits may enable a three-part system exhibiting a low-latency and high bandwidth in-package memory (e.g., that performs analogously to an on-chip SRAM), a highly functional SoC, and a high-capacity storage (e.g., DRAM) with reduced cost and cycle time and a reduced package height. This reduced package height may be beneficial in meeting form factor requirements for use of the disclosed systems and methods in space-constrained mobile devices, such as virtual reality (VR) headsets and augmented reality (AR) glasses. The reduced cost and cycle time may be beneficial in achieving space-constrained mobile devices, such as VR headsets and AR glasses, at reduced time and cost.

### EXAMPLE EMBODIMENTS

Example 1: A semiconductor device package may include a fanout package structure including one or more functional chips, a system on chip mounted face down on the fanout package structure and bonded face to face with the one or more functional chips, and an additional functional chip mounted on and bonded to the system on chip.

Example 2: The semiconductor device package of Example 1, wherein the additional functional chip is mounted back to back on the system on chip by an adhesive and bonded to the system on chip by wire bonding.

Example 3: The semiconductor device package of any of Examples 1 and 2, wherein the additional functional chip is mounted face to back on the system on chip and a face of the additional functional chip is bonded to through silicon vias in the system on chip.

Example 4: The semiconductor device package of any of Examples 1 to 3, wherein the system on chip is mounted on a redistribution layer of the fanout package structure by at least one of copper pillars or solder balls.

Example 5: The semiconductor device package of any of Examples 1 to 4, wherein the one or more functional chips correspond to an in-package high speed local memory that performs analogously to an on-chip static random access memory.

Example 6: The semiconductor device package of any of Examples 1 to 5, wherein the additional functional chip corresponds to a dynamic random access memory.

Example 7: The semiconductor device package of any of Examples 1 to 6, further comprising a mold material surrounding the system on chip and the additional functional chip.

Example 8: A method may include mounting a system on chip face down on a fanout package structure in a manner that bonds the system on chip face to face with one or more functional chips included in the fanout package structure, mounting an additional functional chip on the system on chip, and bonding the additional functional chip to the system on chip.

Example 9: The method of Example 8, wherein mounting the additional functional chip includes mounting the additional functional chip back to back on the system on chip by an adhesive.

Example 10: The method of any of Examples 8 and 9, wherein bonding the additional functional chip includes bonding the additional functional chip to the system on chip by wire bonding.

Example 11: The method of any of Examples 8 to 10, wherein mounting the additional functional chip includes mounting the additional functional chip face to back on the system on chip.

Example 12: The method of any of Examples 8 to 11, wherein bonding the additional functional chip includes bonding a face of the additional functional chip to through silicon vias in the system on chip.

Example 13: The method of any of Examples 8 to 12, wherein the system on chip is mounted on a redistribution layer of the fanout package structure by at least one of copper pillars or solder balls.

Example 14: The method of any of Examples 8 to 13, wherein the one or more functional chips correspond to an in-package high speed local memory that performs analogously to an on-chip static random access memory.

Example 15: The method of any of Examples 8 to 14, wherein the additional functional chip corresponds to a dynamic random access memory.

Example 16: The method of any of Examples 8 to 15, further comprising:
surrounding the system on chip and the additional functional chip with a mold material.

Example 17: A system may include a system on chip mounted face down on a top redistribution layer of a fanout package and a functional chip mounted on the system on chip.

Example 18: The system of Example 17, wherein the functional chip is mounted face up atop the system on chip and is bonded to the system on chip using wire bonds that connect a face of the functional chip to the top redistribution layer of the fanout package.

Example 19: The system of any of Examples 17 and 18, wherein the functional chip is mounted face down atop the system on chip and is bonded to the system on chip by through silicon vias in the system on chip.

Example 20: The system of any of Examples 17 to 19, wherein the functional chip corresponds to a dynamic random access memory.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 500 in FIG. 5) or that visually immerses a user in an artificial reality (such as, e.g., virtual-reality system 600 in FIG. 6). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 5, augmented-reality system 500 may include an eyewear device 502 with a frame 510 configured to hold a left display device 515(A) and a right display device 515(B) in front of a user's eyes. Display devices 515(A) and 515(B) may act together or independently to present an image or series of images to a user. While augmented-reality system 500 includes two displays, embodiments of this disclosure may be implemented in augmented-reality systems with a single NED or more than two NEDs.

In some embodiments, augmented-reality system 500 may include one or more sensors, such as sensor 540. Sensor 540 may generate measurement signals in response to motion of augmented-reality system 500 and may be located on substantially any portion of frame 510. Sensor 540 may represent one or more of a variety of different sensing mechanisms, such as a position sensor, an inertial measurement unit (IMU), a depth camera assembly, a structured light emitter and/or detector, or any combination thereof. In some embodiments, augmented-reality system 500 may or may not include sensor 540 or may include more than one sensor. In embodiments in which sensor 540 includes an IMU, the IMU may generate calibration data based on measurement signals from sensor 540. Examples of sensor 540 may include, without limitation, accelerometers, gyroscopes, magnetometers, other suitable types of sensors that detect motion, sensors used for error correction of the IMU, or some combination thereof.

In some examples, augmented-reality system 500 may also include a microphone array with a plurality of acoustic transducers 520(A)-520(J), referred to collectively as acoustic transducers 520. Acoustic transducers 520 may represent transducers that detect air pressure variations induced by sound waves. Each acoustic transducer 520 may be configured to detect sound and convert the detected sound into an electronic format (e.g., an analog or digital format). The microphone array in FIG. 5 may include, for example, ten acoustic transducers: 520(A) and 520(B), which may be designed to be placed inside a corresponding ear of the user, acoustic transducers 520(C), 520(D), 520(E), 520(F), 520(G), and 520(H), which may be positioned at various locations on frame 510, and/or acoustic transducers 520(I) and 520(J), which may be positioned on a corresponding neckband 505.

In some embodiments, one or more of acoustic transducers 520(A)-(J) may be used as output transducers (e.g., speakers). For example, acoustic transducers 520(A) and/or 520(B) may be earbuds or any other suitable type of headphone or speaker.

The configuration of acoustic transducers 520 of the microphone array may vary. While augmented-reality system 500 is shown in FIG. 5 as having ten acoustic transducers 520, the number of acoustic transducers 520 may be greater or less than ten. In some embodiments, using higher numbers of acoustic transducers 520 may increase the amount of audio information collected and/or the sensitivity and accuracy of the audio information. In contrast, using a lower number of acoustic transducers 520 may decrease the computing power required by an associated controller 550 to process the collected audio information. In addition, the position of each acoustic transducer 520 of the microphone array may vary. For example, the position of an acoustic transducer 520 may include a defined position on the user, a defined coordinate on frame 510, an orientation associated with each acoustic transducer 520, or some combination thereof.

Acoustic transducers 520(A) and 520(B) may be positioned on different parts of the user's ear, such as behind the pinna, behind the tragus, and/or within the auricle or fossa. Or, there may be additional acoustic transducers 520 on or surrounding the ear in addition to acoustic transducers 520 inside the ear canal. Having an acoustic transducer 520 positioned next to an ear canal of a user may enable the microphone array to collect information on how sounds arrive at the ear canal. By positioning at least two of acoustic transducers 520 on either side of a user's head (e.g., as binaural microphones), augmented-reality system 500 may simulate binaural hearing and capture a 3D stereo sound field around about a user's head. In some embodiments, acoustic transducers 520(A) and 520(B) may be connected to augmented-reality system 500 via a wired connection 530, and in other embodiments acoustic transducers 520(A) and 520(B) may be connected to augmented-reality system 500 via a wireless connection (e.g., a BLUETOOTH connection). In still other embodiments, acoustic transducers 520(A) and 520(B) may not be used at all in conjunction with augmented-reality system 500.

Acoustic transducers 520 on frame 510 may be positioned in a variety of different ways, including along the length of the temples, across the bridge, above or below display devices 515(A) and 515(B), or some combination thereof. Acoustic transducers 520 may also be oriented such that the microphone array is able to detect sounds in a wide range of directions surrounding the user wearing the augmented-reality system 500. In some embodiments, an optimization process may be performed during manufacturing of augmented-reality system 500 to determine relative positioning of each acoustic transducer 520 in the microphone array.

In some examples, augmented-reality system 500 may include or be connected to an external device (e.g., a paired device), such as neckband 505. Neckband 505 generally represents any type or form of paired device. Thus, the following discussion of neckband 505 may also apply to various other paired devices, such as charging cases, smart watches, smart phones, wrist bands, other wearable devices, hand-held controllers, tablet computers, laptop computers, other external compute devices, etc.

As shown, neckband 505 may be coupled to eyewear device 502 via one or more connectors. The connectors may be wired or wireless and may include electrical and/or non-electrical (e.g., structural) components. In some cases, eyewear device 502 and neckband 505 may operate independently without any wired or wireless connection between them. While FIG. 5 illustrates the components of eyewear device 502 and neckband 505 in example locations on eyewear device 502 and neckband 505, the components may be located elsewhere and/or distributed differently on eyewear device 502 and/or neckband 505. In some embodiments, the components of eyewear device 502 and neckband 505 may be located on one or more additional peripheral devices paired with eyewear device 502, neckband 505, or some combination thereof.

Pairing external devices, such as neckband 505, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 500 may be provided by a paired device or shared between a paired device and an eyewear device, thus reducing the weight, heat profile, and form factor of the eyewear device overall while still retaining desired functionality. For example, neckband 505 may allow components that would otherwise be included on an eyewear device to be included in neckband 505 since users may tolerate a heavier weight load on their shoulders than they would tolerate on their heads. Neckband 505 may also have a larger surface area over which to diffuse and disperse heat to the ambient environment. Thus, neckband 505 may allow for greater battery and computation capacity than might otherwise have been possible on a stand-alone eyewear device. Since weight carried in neckband 505 may be less invasive to a user than weight carried in eyewear device 502, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 505 may be communicatively coupled with eyewear device 502 and/or to other devices. These other devices may provide certain functions (e.g., tracking, localizing, depth mapping, processing, storage, etc.) to augmented-reality system 500. In the embodiment of FIG. 5, neckband 505 may include two acoustic transducers (e.g., 520(I) and 520(J)) that are part of the microphone array (or potentially form their own microphone subarray). Neckband 505 may also include a controller 525 and a power source 535.

Acoustic transducers 520(I) and 520(J) of neckband 505 may be configured to detect sound and convert the detected sound into an electronic format (analog or digital). In the embodiment of FIG. 5, acoustic transducers 520(I) and 520(J) may be positioned on neckband 505, thereby increasing the distance between the neckband acoustic transducers 520(I) and 520(J) and other acoustic transducers 520 positioned on eyewear device 502. In some cases, increasing the distance between acoustic transducers 520 of the microphone array may improve the accuracy of beamforming performed via the microphone array. For example, if a sound is detected by acoustic transducers 520(C) and 520(D) and the distance between acoustic transducers 520(C) and 520(D) is greater than, e.g., the distance between acoustic transducers 520(D) and 520(E), the determined source location of the detected sound may be more accurate than if the sound had been detected by acoustic transducers 520(D) and 520(E).

Controller 525 of neckband 505 may process information generated by the sensors on neckband 505 and/or augmented-reality system 500. For example, controller 525 may process information from the microphone array that describes sounds detected by the microphone array. For each detected sound, controller 525 may perform a direction-of-arrival (DOA) estimation to estimate a direction from which the detected sound arrived at the microphone array. As the microphone array detects sounds, controller 525 may populate an audio data set with the information. In embodiments in which augmented-reality system 500 includes an inertial measurement unit, controller 525 may compute all inertial and spatial calculations from the IMU located on eyewear device 502. A connector may convey information between augmented-reality system 500 and neckband 505 and between augmented-reality system 500 and controller 525. The information may be in the form of optical data, electrical data, wireless data, or any other transmittable data form. Moving the processing of information generated by augmented-reality system 500 to neckband 505 may reduce weight and heat in eyewear device 502, making it more comfortable to the user.

Power source 535 in neckband 505 may provide power to eyewear device 502 and/or to neckband 505. Power source 535 may include, without limitation, lithium-ion batteries, lithium-polymer batteries, primary lithium batteries, alkaline batteries, or any other form of power storage. In some cases, power source 535 may be a wired power source. Including power source 535 on neckband 505 instead of on eyewear device 502 may help better distribute the weight and heat generated by power source 535.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 600 in FIG. 6, that mostly or completely covers a user's field of view. Virtual-reality system 600 may include a front rigid body 602 and a band 604 shaped to fit around a user's head. Virtual-reality system 600 may also include output audio transducers 606(A) and 606(B). Furthermore, while not shown in FIG. 6, front rigid body 602 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 500 and/or virtual-reality system 600 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 500 and/or virtual-reality system 600 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 500 and/or virtual-reality system 600 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device package, comprising:
a fanout package structure including one or more functional chips;
a system on chip mounted face down on the fanout package structure and bonded face to face with the one or more functional chips; and
an additional functional chip mounted on and bonded to the system on chip.

2. The semiconductor device package of claim 1, wherein the additional functional chip is mounted back to back on the system on chip by an adhesive and bonded to the system on chip by wire bonding.

3. The semiconductor device package of claim 1, wherein the additional functional chip is mounted face to back on the system on chip and a face of the additional functional chip is bonded to through silicon vias in the system on chip.

4. The semiconductor device package of claim 1, wherein the system on chip is mounted on a redistribution layer of the fanout package structure by at least one of copper pillars or solder balls.

5. The semiconductor device package of claim 1, wherein the one or more functional chips correspond to an in-package high speed local memory that performs analogously to an on-chip static random access memory.

6. The semiconductor device package of claim 1, wherein the additional functional chip corresponds to a dynamic random access memory.

7. The semiconductor device package of claim 1, further comprising a mold material surrounding the system on chip and the additional functional chip.

8. A method, comprising:
mounting a system on chip face down on a fanout package structure in a manner that bonds the system on chip face to face with one or more functional chips included in the fanout package structure;
mounting an additional functional chip on the system on chip; and
bonding the additional functional chip to the system on chip.

9. The method of claim 8, wherein mounting the additional functional chip includes:
mounting the additional functional chip back to back on the system on chip by an adhesive.

10. The method of claim 9, wherein bonding the additional functional chip includes:
bonding the additional functional chip to the system on chip by wire bonding.

11. The method of claim 8, wherein mounting the additional functional chip includes:
mounting the additional functional chip face to back on the system on chip.

12. The method of claim 11, wherein bonding the additional functional chip includes:
bonding a face of the additional functional chip to through silicon vias in the system on chip.

13. The method of claim 8, wherein the system on chip is mounted on a redistribution layer of the fanout package structure by at least one of copper pillars or solder balls.

14. The method of claim 8, wherein the one or more functional chips correspond to an in-package high speed local memory that performs analogously to an on-chip static random access memory.

15. The method of claim 8, wherein the additional functional chip corresponds to a dynamic random access memory.

16. The method of claim 8, further comprising:
surrounding the system on chip and the additional functional chip with a mold material.

17. A system comprising:
a system on chip mounted face down on a top redistribution layer of a fanout package; and
a functional chip mounted on the system on chip.

18. The system of claim 17, wherein the functional chip is mounted face up atop the system on chip and is bonded to the system on chip using wire bonds that connect a face of the functional chip to the top redistribution layer of the fanout package.

19. The system of claim 17, wherein the functional chip is mounted face down atop the system on chip and is bonded to the system on chip by through silicon vias in the system on chip.

20. The system of claim 18, wherein the functional chip corresponds to a dynamic random access memory.
